(19) United States
(12) Patent Application Publication
(10) Pub. No.: US 2002/0127821 A1
(43) Pub. Date: Sep. 12, 2002

(54) Process for the production of thinned wafer

(76) Inventors: Kazuyuki Ohya, Tokyo (JP); Isao Tanaka, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/025,891

(22) Filed: Dec. 26, 2001

(30) Foreign Application Priority Data
Dec. 28, 2000 (JP) 401077/00
Jul. 25, 2001 (JP) 224008/01

(51) Int. Cl. H01L 21/30; H01L 21/46

(52) U.S. Cl. 438/459

(57) ABSTRACT

A process for the production of a thinned wafer, comprising bonding the circuit surface (surface A) of a semiconductor wafer (a) to a holding substrate (b) with an adhesive film (c), grinding and polishing the back surface (surface B) of the semiconductor wafer to thin the semiconductor wafer, carrying out the metallization of the back surface (surface B) and the like as required, and then separating the thinned wafer from the holding substrate (b),

wherein a thermoplastic resin film is used as the adhesive film (c) and the above bonding of the circuit surface (surface A) of the semiconductor wafer (a) to the holding substrate (b) is carried out at a bonding temperature selected from the range of from +10° C. to +120° C. of glass transition point of the thermoplastic resin film or the range of from −40° C. to +20° C. of melting point of the thermoplastic resin film.

### FIELD OF THE INVENTION

The present invention relates to a process for the production of a thinned wafer, comprising back-grinding the back surface of a semiconductor wafer to decrease the thickness of the semiconductor wafer, carrying out the metallization of the back surface, etc., as required, and then separating the thinned wafer from a holding substrate (b).

### DESCRIPTION OF PRIOR ARTS

For the purposes of radiating heat generated from a semiconductor device, improving electrical characteristics, decreasing electric power consumption and improving stability, a wafer is thinned by grinding and polishing the back surface of the wafer.

In a conventional wafer-thinning process which decreases the thickness of a wafer to 200 to 300 μm, generally, a wafer is back-ground by a method (grinding protection tape method) in which the wafer is supported with a tape for back-grinding (grinding protection tape, dicing tape, etc.).

For example, JP-A-2000-212524 proposes a semiconductor wafer protection/adhesion tape obtained by forming an adhesive layer on a surface of a substrate film made of a thermoplastic resin. According to the above publication, a warp can be reduced when a PET film having a high elastic modulus is used as the above substrate film.

However, the grinding protection tape method has the limit of thinning, since the warp of the thinned wafer is large because of a residual stress between the protection tape and the wafer. The limit of thinning the thickness of a wafer is approximately 200 to 300 μm. Further, another defect is that an adhesive is apt to remain on the wafer. In addition, the protection tape and the adhesive have low heat resistance and are poor in chemical resistance. From this respect, when preliminary steps of chemically washing and polishing the back surface of a thinned wafer or a step for forming a semiconductor circuit pattern on the back surface are carried out, it is required to separate the protection tape before these steps. The above preliminary steps are indispensable when a pattern is made on the back surface.

Further, there is a method in which a wafer is ground and polished with the wafer bonding to a hard holding substrate at a grinding time. When a silicon wafer is used, the wafer itself is used as the hard holding substrate. In addition, there is used a glass, a silica glass, sapphire or the like. A pressure sensitive adhesive double coated tape or wax is used for the bonding and holding.

For example, JP-A-2000-331962 uses a glass plate as a holding substrate and a wafer is bonded to the glass plate with a pressure sensitive adhesive double coated tape. However, this method also has the above problems found when an adhesive is used.

In JP-A-8-22969, a wafer is bonded to a glass holding substrate with wax. The method using wax has problems that bubbles are apt to remain on a bonding surface, that surface accuracy is poor, and that the removal of wax after the separation requires considerable efforts. Further, the heat resistance is low (approximately 150° C. or lower).

Furthermore, there is a method that uses a silicon wafer as a holding substrate. However, in this method, the bonding is unstable. When the bonding is carried out with sufficient stability, the separation is extremely difficult.

Concerning a semiconductor or compound semiconductor used for a discrete use or a millimeter wave use, there is the necessity of thinning the thickness of the semiconductor or compound semiconductor to 100 μm or less, or to approximately 30 μm in some cases.

Further, it has been required to enlarge the size of a wafer from 5 inches→6 inches→8 inches→12 inches. The enlargement of the wafer size for increasing productivity accompanies problems which inversely reduce productivity, such as a decrease in thickness accuracy or a decrease in yield due to an increase in the number of cracks at processing steps.

### SUMMARY OF THE INVENTION

It is an object of the invention to provide a method of thinning a wafer, which method causes little warp, has a high surface accuracy and causes no remaining adhesive.

It is another object of the present invention to facilitate the achievement of a balance between adhesive strength and separation easiness in a method which uses a thermoplastic resin film having no adhesive (stickiness) layer as an adhesive film.

It is further another object of the present invention to provide a method which enables the separation of a wafer from an adhesive film at an interface therebetween even in the case of the use of a wafer having an insulating coating of a resin or a protective coating of a resin on a circuit surface.

According to the present invention, there is provided a process for the production of a thinned wafer, comprising bonding the circuit surface (surface A) of a semiconductor wafer (a) to a holding substrate (b) with an adhesive film (c), grinding and polishing the back surface (surface B) of the semiconductor wafer to thin the semiconductor wafer, carrying out the metallization of the back surface (surface B) and the like as required, and then separating the thinned wafer from the holding substrate (b), wherein a thermoplastic resin film is used as the adhesive film (c) and the above bonding of the circuit surface (surface A) of the semiconductor wafer (a) to the holding substrate (b) is carried out at a bonding temperature selected from the range of from +10° C. to +120° C. of glass transition point of the thermoplastic resin film or the range of from −40° C. to +20° C. of melting point of the thermoplastic resin film.

Further, according to the present invention, there is provided a process as recited above, wherein the holding substrate (b) is obtained by impregnating an inorganic continuously porous sintered substrate formed of at least one selected from the group consisting of aluminum nitride, aluminum nitride-boron nitride, silicon carbide, aluminum nitride-silicon carbide-boron nitride, alumina-boron nitride and silicon nitride-boron nitride, with a heat-resistant resin and curing the impregnated heat-resistant resin.

Further, according to the present invention, there is provided a process as recited above, wherein the bonding is carried out under heat under a reduced pressure under conditions of a pressure selected from 0.05 to 5 Mpa and a treatment time selected from 3 to 90 minutes.

Further, according to the present invention, there is provided a process as recited above, wherein the adhesive film is a thermoplastic resin film of which both surfaces are different from each other in a glass transition point or melting point and the thermoplastic resin surface (front side) having a higher glass transition point or higher melting point is bonded to the circuit surface (surface A) side of the semiconductor wafer (a).

Further, according to the present invention, there is provided a process as recited above, wherein the bonding is carried out at a bonding temperature selected from the range of from +10° C. to +120° C. of glass transition point of the thermoplastic resin on that surface (back side) of the thermoplastic resin film which is to be bonded to the holding substrate (b) or the range of from −40° C. to +20° C. of melting point of the thermoplastic resin of the back surface.

Further, according to the present invention, there is provided a process as recited above, wherein the adhesive film (c) has grooves for a liquid or gas to enter on the thermoplastic resin film surface (front side) to be brought into contact with the circuit surface (surface A) of the wafer (a).

Further, according to the present invention, there is provided a process as recited above, wherein the separation of the thinned wafer is carried out after the thinned wafer/holding substrate (b) is treated with water, alcohol, a water-alcohol mixed solution or steam having a temperature of from 25 to 140° C.

### DETAILED DESCRIPTION OF THE INVENTION

The constitution of the present invention will be explained hereinafter.

Semiconductor Wafer (a)

The semiconductor wafer (a) of the present invention includes element type semiconductor such as silicon (Si), germanium (Ge), selenium (Se), tin (Sn), tellurium (Te), etc., and compound semiconductor such as gallium-arsenic(GaAs), GaP, GaSb, AlP, AlAs, AlSb, InP, InAs, InSb, ZnSe, ZnTe, CdS, CdSe, CdTe, AlGaAs, GaInAs, AlInAs, InGaP, AlGaInAs, etc.

Holding Substrate (b)

The holding substrate (b) of the present invention must have high heat resistance, high mechanical strength and high chemical resistance. The coefficient of thermal expansion of the holding substrate and the coefficient of thermal expansion of the semiconductor wafer are in the substantially same range. For decreasing a warp after the bonding, facilitating the application of a wafer to a thinning step and facilitating the separation of the semiconductor wafer from the holding substrate, furthermore, the coefficient of thermal expansion of the holding substrate is preferably a little larger than the coefficient of thermal expansion of the semiconductor wafer and the difference is preferably in a certain range. The holding substrate (b) of the present invention is selected from materials based on inorganic substances such as alumina, aluminum nitride, boron nitride, silicon carbide and borosilicate glass.

In the present invention, there are preferably used those which obtained by impregnating continuous pores of an inorganic continuously porous sintered body having at least 0.5 vol %, more preferably 2 to 35 vol %, of continuous pores having an average pore diameter of 0.1 to 10 μm, with a heat resistant resin and curing the impregnated resin.

Preferable examples of the inorganic continuously porous sintered body include aluminum nitride(AlN), aluminum nitride-boron nitride(AlN-h-BN), silicon carbide(SiC), aluminum nitride-silicon carbide-boron nitride(AlN-SiC-h-BN), alumina-boron nitride(Al₂O₃-h-BN) and silicon nitride-boron nitride(Si₃N₄-h-BN). In addition to these examples, it includes zirconium oxide-aluminum nitride-boron nitride (ZrO₂—AlN—h-BN), zirconium oxide-alumina-boron nitride(ZrO₂—Al₂O₃-h—BN), alumina-titanium oxide-boron nitride(Al₂O₃—TiO₂-h-BN), amorphous carbon and carbon fiber reinforced carbon.

The heat resistant resin used for the impregnation of the inorganic substrate can be selected from aromatic polyfunctional cyanate ester compounds of an addition polymerization type or cross-linking type heat resistant resin, disclosed in JP-A-8-244163, JP-A-9-314732, etc., disclosed by the present inventors. Further, there can be used a solution of a polyimide resin or a polyimide resin precursor. In particular, as a resin which can be preferably used at high temperatures, there is listed a silicon resin having a high heat resistance, for example, a ladder type silicon oligomer (trade name: Glass Resin, product Nos. GR650, GR908, etc., supplied by OI-NEG TV Products, Inc.).

When the inorganic substrate is impregnated with the resin, it is preferred to carry out a surface treatment in order to improve the affinity between the surface of the inorganic continuously porous sintered body including continues pore surfaces and the resin. The surface treatment is preferably carried out by impregnating the inorganic continuously porous sintered body with a solution of an organometallic compound containing aluminum, titanium or silicon or an organometallic compound which is a prepolymer having a weight average molecular weight of less than 10,000 under vacuum, air-drying the impregnated inorganic continuously porous sintered body to remove the solvent, preliminarily heat-treating it, and pyrolyzing the organometallic compound at a maximum temperature of 850° C. or lower.

The execution of the present surface treatment improves the affinity with the impregnation resin and further improves the adhesive properties to the thermoplastic resin film used for the bonding.

Adhesive Film (c)

The thermoplastic resin film suited for the purpose of the present invention may be crystalline or amorphous, so long as it softens at a certain temperature or higher and it does not have too strong adhesion. Specifically, it includes thermoplastic resin films cited below as thermoplastic resin films usable for a two-layered film to be described later. A suitable thermoplastic resin film is selected in consideration of conditions.

It is preferable that the adhesive film does not contain an additive such as a plasticizer and the like in view of the prevention of transcription of impurities to the wafer. However, the adhesive film can contain a lubricant and other additives in order to improve the separability thereof from the wafer.

Further, the resin film may be an oriented resin film or a non-oriented resin film. The thickness of the resin film is 10 to 100 μm, preferably 15 to 40 μm. Further, the resin film can be processed by a corona discharge treatment for improving the adhesive strength. Furthermore, the adhesive film can be emboss-finished or coated with a silicon resin in order to increase the separability.

Further, in the present invention, there is preferably used a thermoplastic resin film of which both surfaces are different from each other in a glass transition point or melting point (thermally softening point). Generally, the thermoplastic resin film satisfying the above requirement is a multilayer film having two or three layers or more. At least both surfaces (front and back surfaces) are respectively made of thermoplastic resins different from each other.

The bonding temperatures and pressures for the front and back surfaces of the adhesive film are the same. Therefore, the bonding of the thermoplastic resin (A) having a higher thermally-softening point is carried out at a lower temperature side (weak bonding) and the bonding of the thermoplastic resin (B) having a lower thermally-softening point is carried out at a higher temperature side (strong bonding).

The thermoplastic resin (A) forming the surface having a higher thermally-softening point, which surface is to be bonded to the semiconductor wafer surface, specifically includes polyethylene terephthalate (PET), polybutylene terephthalate (PBT), polycarbonate (PC), polyamide (PA), polyimide (PI), polysulfone (PPS) and polyamide imide (PAI).

The thermoplastic resin (B) forming the surface having a lower thermally-softening point, which surface is to be bonded to the surface of the holding substrate (b), is preferably selected from resins having a thermally-softening point lower than that of the thermoplastic resin (A) by approximately several tens to 120° C. Specifically, it includes polyethylene (PE), ethylene-vinylacetate copolymer (EVAc), ethylene-vinylalcohol copolymer (EVA), polypropylene (PP), polystyrene (PS), polymethyl methacrylate (PMMA), polycarbonate (PC) and polyamide (PA). Polyimide (PI) which has a lower thermally-softening point can be also used.

Generally, the present adhesive film (c) is produced by an extrusion lamination or a dry lamination. In order to prevent impurities from being transcribed to the wafer, the present adhesive film (c) is preferably made from a thermoplastic resin which does not contain a plasticizer, a lubricant, a stabilizer, a colorant and other additives which are usually added. However, it is an preferable embodiment that additives which promote the separation are properly added as required after examining the kind of an additive and the facility of removal of impurities when the impurities are transcribed.

Further, the adhesive film (c) may be an oriented film or a non-oriented film.

The thickness of the adhesive film is 10 to 100 μm, preferably 15 to 40 μm. Further, the adhesive film can be processed by a corona discharge treatment for improving the adhesive strength. There can be also preferably used an adhesive film which is emboss-finished or coated with a silicon resin or an adhesive film which is made of a resin composition containing an inorganic compound fine powder having a water or organic solvent swelling property in order to increase the separability.

Further, there can be used an adhesive film having a thermoplastic resin surface which has grooves for the entry of a liquid or a gas and is to be bonded to the circuit surface (surface A) of the wafer (a).

Thinning Steps

The present invention uses the above materials as principal structural materials and, generally, carries out the present thinning steps consisting of the following (1) to (4).

(1) The single-side circuit surface (surface A, also called “front surface” or “first surface”) of a semiconductor wafer (a) is bonded to a holding substrate (b) with an adhesive film (c).

(2) The back surface (surface B, also called “back surface” or “second surface”) of the semiconductor wafer is ground and polished to thin the wafer.

(3) The mettalization of the above surface (surface B), the formation of circuits and etc. are carried out as required.

(4) The thinned wafer is separated from the holding substrate (b).

Concerning the bonding in the present invention, first, for maintaining the flatness and smoothness of the wafer, the semiconductor wafer (a) is bonded and held to/on the holding substrate with a high degree of reliability in the steps of (2) and (3), to prevent the corrosion of the circuit surface or the like and to prevent a distortion which is liable to be caused after the thinning of the wafer due to a difference in coefficient of thermal expansion between the circuit surface of the wafer and the base material of the wafer. Particularly, the above distortion is caused when a thinner wafer is made. Secondly, it is necessary that the bonding allows the wafer to be easily separated from the holding substrate after the completion of the above steps.

The bonding temperature in the above step (1) is properly selected from the range of from +10° C. to +120° C. of glass transition point of the thermoplastic resin film or the range of from −40° C. to +20° C. of melting point of the thermoplastic resin film in consideration of adhesion strength, separability and the like. An appropriate bonding pressure and an appropriate bonding temperature are in the relation of inverse proportion. The range of a temperature usable is the above-described range.

When the bonding is weak, i.e., when the bonding temperature is too low, the wafer is separated during the thinning steps. When the bonding is strong, i.e., when the bonding temperature is too high, the separation of the wafer after the thinning steps is difficult or impossible. Further, when the circuit surface of the wafer has an insulating coating of a resin or a protective coating of a resin, the bonding between the resin of the insulating coating or the protective coating and the thermoplastic resin film becomes strong so that the separation at an interface between the circuit surface of the wafer and the adhesive film becomes difficult. Accordingly, the adhesive film remains on the thinned wafer side and its handling is difficult.

For the above reasons, preferably, an adhesive film (c) of which both surfaces are different from each other in a glass transition point or melting point (thermally-softening point) is selected and the adhesive film (c) is bonded to the circuit surface (surface A) of the semiconductor wafer (a) such that the thermoplastic resin (A) surface having a higher glass transition point or melting point (thermally-softening point) is preferably bonded to the circuit surface (surface A). The bonding temperature is properly selected from the range of from +10° C. to +120° C. of glass transition point of the thermoplastic resin (B) to be bonded to the holding substrate (b) or the range of from −40° C. to +20° C. of melting point of the thermoplastic resin (B).

As a result, generally, the adhesive strength of the thermoplastic resin (A) side is set such that the adhesive strength on the thermoplastic resin (A) side becomes weaker than that of the thermoplastic resin (B).

Generally, when a temperature on the higher temperature side is selected as a bonding temperature, stronger bonding can be performed. Inversely, when a temperature on the lower temperature side is selected as a bonding temperature, weaker bonding can be performed. Both the front and back surfaces similarly have these tendencies. When a difference in a thermally-softening point between thermoplastic resins used for front and back surfaces is large, bonding in which the adhesive strength difference between the front and back surfaces is large can be selected. When a difference in a thermally-softening point between thermoplastic resins used for front and back surfaces is small, bonding in which the adhesive strength difference between the front and back surfaces is small can be selected.

When the circuit surface of the wafer has an insulating coating of a resin or a protective coating of a resin, adhesive strength becomes strong. When a step of forming a circuit on the back surface and other steps exist after the thinning, heating in the above step increases the adhesive strength.

In consideration of the above reasons, a combination of resins forming a separable film and a bonding condition can be selected and adjusted for bonding and holding the semiconductor wafer (a) to/on the holding substrate with a high degree of reliability in the steps (2) and (3).

Generally, the above-described bonding of the present invention is preferably carried out under a pressure-reduced atmosphere. The press pressure is in the maximum pressure range of from 0.05 to 5 Mpa, preferably from 0.1 to 1 Mpa. The holding time is generally selected from the range of from 3 to 90 minutes.

Concerning the loading method of a press pressure, it is necessary that a low-pressure load is possible. In addition, there is especially selected a press machine free from or almost free from a pressure (to be called “counter pressure” hereinafter) because of a thermal expansion or a press method absorbing the counter pressure.

That is, when pressure is loaded onto a material to be pressed, this material is thermally expanded since the amount of heat transfer rapidly increases. For example, when an air-plunger type press machine is used, the air plunger works as a damper and absorbs the thermal expansion around a set pressure so that no excessive pressure takes place. When an oil plunger type press machine is used, the oil plunger does not work as a damper or the oil plunger hardly works as a damper so that the thermal expansion can not be absorbed. Therefore, when an oil plunger type press machine is used and a general layout method of press materials is adopted, troubles such as damage of a semiconductor wafer are liable to take place. Therefore, it is necessary to dispose a material which absorbs pressure due to thermal expansion, for example a cushion (reverse cushion), around the material to be pressed.

In the step (2) of the present invention, the back surface (surface B) of the semiconductor wafer (a) in the semiconductor wafer (a)/holding substrate (b) integrated above is ground and the ground back surface is generally polished by CMP to thin the semiconductor wafer (a). After the step (2), the step (3) of forming back circuits on the back surface (surface B) is carried out as required. When the step (3) is omitted, no strengthening of adhesion strength occurs as described before. Therefore, the purpose is attained when a material for the adhesive film (c) and a bonding condition are selected in consideration of the treatment state of the surface (surface A) of the semiconductor wafer (a), particularly in consideration of the presence or absence of the use of an organic protective coating or an insulating coating, such that the thinned semiconductor wafer (a) can be separated without any damage.

When the step (3) is carried out, the step (3) includes a stage of preliminarily treating the polished back surface of the wafer with a chemical for the formation of circuits and a vacuum heating stage of metallization, etc., after the above preliminary treatment stage. Accordingly, an adhesive film (c) which is made of a resin that has resistance to a chemical used in the preliminary treatment stage, etc., and generates substantially no gas under vacuum and heat and which is separable even when the adhesive strength is strengthened by the vacuum heating stage is selected. In particular, the step (3) is a step which can be called a part of semiconductor production process. It is an important element to select physical properties which satisfy chemical resistance, heat resistance or other necessary properties in order to put the present process to practical use.

Next, in the step (4), the thinned wafer and the holding substrate are separated from each other such that the adhesive film preferably keeps bonding to the holding substrate after the separation.

In the separation, first, the thinned wafer/holding substrate is subjected to a treatment for weakening adhesive strength (adhesive strength alleviation treatment) with water, alcohol, a water-alcohol mixed solution, an ammonia aqueous solution, an amine aqueous solution or aqueous vapor having a temperature of 25 to 140° C., preferably 50 to 90° C. The adhesive strength alleviation treatment is carried out by, for example, dipping the thinned wafer/holding substrate in a bath of any one of the above liquids. After the above adhesive strength alleviation treatment, the separation of the thinned wafer from the holding substrate is carried out.

Owing to the adhesive strength alleviation treatment, an ingredient of the liquid used diffuses on the bonding interface. When the ingredient of the liquid infiltrates the central part thereof, the separation is extremely easy. Heating can promote the diffusion of the liquid onto the bonding interface. Otherwise, when there is no problem such as damage of a semiconductor circuit, a supersonic wave treatment can be used in combination.

Further, when no liquid infiltrates in the treatment step of the back surface or the infiltration of the liquid causes no harm on the circuit surface, grooves for a liquid or gas to enter can be preferably formed on that thermoplastic resin surface of the adhesive film (c) which is to be bonded to the circuit surface of the wafer (a).

Although the separation after the alleviation treatment can be carried out manually, it is preferred to use a separating machine.

When a separating exfoliating machine is used, the holding substrate is adsorbed to an adsorption board of the separating machine under a reduced pressure. An adsorption board for an opposite surface is applied to the thinned wafer, and the separation is generally carried out by exerting a force for moving the adsorption board while reducing a pressure by sucking, such that the thinned wafer and the holding substrate are separated therebetween from one side.

### EXAMPLES

The present invention will be explained more in detail with reference to Examples hereinafter, in which “part” stands for “part by weight” and “%” stands for “% by weight” unless otherwise specified.

### Example 1

Preparation of Holding Substrate (b)

A disc (thickness 0.65 mm, diameter 125 mm) of an aluminum nitride-boron nitride porous sintered body (h-BN 13%, bulk density 2.45, true porosity 20.6 vol %, average pore diameter 0.66 μm) was cleaned by heating at 700° C. and then impregnated with a solution of aluminum tris(ethylacetylacetonate) and the impregnated solution was air-dried. Then, the air-dried disc was calcined at a maximum temperature of 750° C. to generate aluminum oxide on the pore surfaces including the inside of the pores. Then, the calcined disk was impregnated with a solution of a ladder type silicon oligomer (trade name: Glass Resin GR908, supplied by OI-NEG TV Products, Inc.) and the impregnated solution was dried. These impregnation and drying were repeated. Then, the resultant disk was thermally cured. Then, the surface thereof was polished to obtain a holding substrate (to be referred to as “ALN” hereinafter) having a thickness of 0.625 mm and a surface roughness Ra of 0.3 μm.

Bonding and Grinding of Wafer

A polystyrene film (thickness 30 μm, glass transition point =100° C.) was cut to obtain a polystyrene film having a diameter of 125 mm. The polystyrene film having a diameter of 125 mm was placed on the holding substrate and a silicon wafer (thickness 625 μm, diameter 125 mm) was placed thereon. The resultant set was placed in a tool made of aluminum and the set in the tool was disposed between heat plates of a vacuum press.

The temperature of the heat plates was increased up to 130° C. in advance. The pressure in an ambient atmosphere was decreased to 10 mmHg or less, then pressing was performed by applying a surface pressure of 0.2 MPa, and the above pressure and the above temperature were maintained for 10 minutes. The reduced pressure in the ambient atmosphere was opened to atmosphere. Then, it was allowed to cool to obtain a wafer-bonded holding substrate (to be referred to as “Si/holding substrate” hereinafter). The warp thereof was +120 μm.

The obtained Si/holding substrate was placed in water and ultrasonic vibration was given to the Si/holding substrate for 30 minutes. However, no separation was found. Then, the Si/holding substrate was ground with a grinder until the wafer had a thickness of 100 μm.

The warp was measured by the following method. The Si/holding substrate was placed on the table of a three-dimensional measuring machine (supplied by Tokyo Seimitsu K.K.) such that the wafer side was the upper side. Heights in ten points of the back surface of the wafer were measured and a difference between the maximum value and the minimum value was considered as warp. Further, a mark (+) was given to a warp toward the wafer side and a mark (−) was given to a warp toward the holding substrate side.

Separation of Wafer

The Si/holding substrate was placed in pure water having a temperature of 80° C. and maintained for 3 hours. Then, the thinned wafer was separated from the holding substrate with a separating machine. The holding substrate and the polystyrene film were also easily separated from each other. The thickness unevenness of the thinned wafer was 100±2 μm.

Example 2

A thinned silicon wafer was obtained in the same manner as in Example 1 except that the bonding temperature was changed from 130° C. to 110° C. The adhesive strength of the polystyrene film and the holding substrate was weaker than that in Example 1.

### Comparative Example 1 and 2

Example 1 was repeated except that the bonding temperature was changed from 130° C. to 150° C. (Comparative Example 1) and 100° C. (Comparative Example 2). In Comparative Example 1, the separation was impossible. In Comparative Example 2, the bonding was not completed.

### Example 3

Example 1 was repeated except that the polystyrene film as an adhesive film was replaced with an ethylene-vinylalcohol copolymer film (melting point 183° C., thickness 20 μm) and that the bonding was carried out at a bonding temperature of 145° C. at a bonding pressure of 0.2 MPa. Both of the bonding and the separation were possible.

A warp before the grinding was +110 μm.

### Comparative Example 3

Example 3 was repeated except that the bonding pressure was changed from 0.2 MPa to 0.075 MPa. In this case, since the bonding pressure was too low, the bonding was impossible.

### Example 4

Example 3 was repeated except that the bonding was carried out at a bonding temperature of 150° C. at a bonding pressure of 0.125 MPa. Although the bonding pressure was decreased, the bonding and the separation were possible.

### Comparative Example 4

Example 3 was repeated except that the bonding was carried out at a bonding temperature of 150° C. at a bonding pressure of 0.2 MPa. The bonding was sufficient but the separation was impossible.

### Example 5

Example 3 was repeated except that the bonding was carried out at a bonding temperature of 170° C. at a bonding pressure of 0.075 MPa. The bonding and the separation were possible.

### Comparative Example 5 and 6

Example 3 was repeated except that the bonding was carried out at a bonding temperature of 170° C. at a bonding pressure of 0.125 MPa (Comparative Example 5) or the bonding was carried out at a bonding temperature of 200° C. at a bonding pressure of 0.075 MPa (Comparative Example 6). In each of Comparative Examples 5 and 6, the bonding was sufficient but the separation was impossible.

### Example 6

Example 1 was repeated except that the polystyrene film as an adhesive film was replaced with a methacrylate resin film (glass transition point 100° C., thickness 35 μm) and that the bonding temperature was changed from 130° C. to 110° C. Both of the bonding and the separation were possible.

A warp before the grinding was +160 μm.

### Example 7

Example 6 was repeated except that the bonding temperature was changed to 180° C. Both of the bonding and the separation were possible. A warp before the grinding was +200 μm.

### Comparative Examples 7 and 8

Example 6 was repeated except that the bonding temperature was changed to 200° C. (Comparative Example 7) and to 95° C. (Comparative Example 8). In Comparative Example 7, the separation was impossible. In Comparative Example 8, the bonding was not completed.

### Example 8

Example 1 was repeated except that the polystyrene film as an adhesive film was replaced with a triacetylcellulose film (glass transition point 130˜140° C., thickness 50 μm) and that the bonding temperature was changed. The bonding temperature at which both the bonding and the separation were possible was 170˜180° C.

The warp of the product bonded at 170° C. was +260 μm.

### Example 9

A polyethylene film (melting point 105˜110° C., thickness 30 μm, raw material=LDPE, a single-side mat-processed product) was used as an adhesive film. The bonding was carried out such that the mat surface of the film came into contact with the holding substrate. Example 1 was repeated except that the bonding temperature was changed.

The bonding temperature at which both the bonding and the separation were possible was 90˜110° C. The warp of the product bonded at 105° C. was +120 μm.

### Example 10

Example 1 was repeated except that the polystyrene film as an adhesive film was replaced with a polypropylene film (melting point 160˜165° C., thickness 60 μm) and that the bonding temperature was changed. The temperature at which both the bonding and the separation were possible was 130˜150° C.

The warp of the product bonded at 130° C. was +200 μm.

### Example 11

Example 1 was repeated except that the polystyrene film as an adhesive film was replaced with a polyvinylidene fluoride film (melting point 156˜170° C., thickness 50 μm) and that the bonding temperature was changed. The temperature at which both the bonding and the separation were possible was 170˜180° C.

### Example 12

A disc (thickness 1.20 mm, diameter 125 mm) of an alumina-boron nitride porous sintered body (h-BN 13%, bulk density 2.32, apparent porosity 24.4 vol %) was cleaned by calcining at 700° C. Then, impregnation with a resin, curing of the impregnated resin and polishing of the surface were carried out in the same manner as in Example 1 except that the above-cleaned disc was used, whereby a holding substrate (to be referred to as “ALO” hereinafter) having a thickness of 1.00 mm and a surface roughness Ra of 0.3 μm was obtained.

Gallium-arsenic(GaAs) having a diameter of 100 mm and a thickness of 0.625 mm was used as a wafer. A polyamide 6 film (melting point 224° C., thickness 25 μm) was used as an adhesive film.

The holding substrate, the wafer and the adhesive film were treated at a bonding temperature of 220° C. similarly to Example 1. The warp was +85 μm.

The separated thinned GaAs wafer had a thickness unevenness of 100±2 μm.

### Comparative Example 9

Example 12 was repeated except that the bonding temperature in Example 12 was changed to 250° C. The bonding was sufficient but the separation was impossible.

### Example 13

Example 12 was repeated except that a methacrylate resin film (glass transition point 100° C., thickness 35 μm) was used as an adhesive film. The temperature range in which both the bonding and the separation were possible was 110˜180° C.

### Example 14

Example 12 was repeated except that an ethylene-vinylalcohol copolymer film (melting point 183° C., thickness 20 μm) was used as an adhesive film. The temperature range in which both the bonding and the separation were possible was 145˜170° C.

Table 1 provides a summary of conditions and results of Examples 1 to 14 and Comparative Examples 1 to 9.

TABLE 1

| | |
|---|---|
| Holding | Adhesive film |

| | wafer | substrate | kind | mp, Tg |
|---|---|---|---|---|
| Ex. 1 | Si | ALN | PS | 100 Tg |
| Ex. 2 | Si | ALN | PS | 100 Tg |
| CEx. 1 | Si | ALN | PS | 100 Tg |
| CEx. 2 | Si | ALN | PS | 100 Tg |
| Ex. 3 | Si | ALN | EVA | 183 mp |
| CEx. 3 | Si | ALN | EVA | 183 mp |
| Ex. 4 | Si | ALN | EVA | 183 mp |
| CEx. 4 | Si | ALN | EVA | 183 mp |
| Ex. 5 | Si | ALN | EVA | 183 mp |
| CEx. 5 | Si | ALN | EVA | 183 mp |
| CEx. 6 | Si | ALN | EVA | 183 mp |
| Ex. 6 | Si | ALN | PMMA | 100 Tg |
| Ex. 7 | Si | ALN | PMMA | 100 Tg |
| CEx. 7 | Si | ALN | PMMA | 100 Tg |
| CEx. 8 | Si | ALN | PMMA | 100 Tg |
| Ex. 8 | Si | ALN | TAC | 130-140 Tg |
| Ex. 9 | Si | ALN | PE | 105-110 mp |
| Ex. 10 | Si | ALN | PP | 160-165 mp |
| Ex. 11 | Si | ALN | PVdF | 156-170 mp |
| Ex. 12 | GaAS | ALO | PA6 | 224 mp |
| CEx. 9 | GaAS | ALO | PA6 | 224 mp |
| Ex. 13 | GaAS | ALO | PMMA | 100 Tg |
| Ex. 14 | GaAS | ALO | EVA | 183 mp |

| | |
|---|---|
| Bonding conditions | Test results |

| | ° C. | MPa | bonding | separation |
|---|---|---|---|---|
| Ex. 1 | 130 | 0.20 | ∘ | ∘ |
| Ex. 2 | 110 | 0.20 | ∘ | ∘ |
| CEx. 1 | 150 | 0.20 | ∘ | x |
| CEx. 2 | 100 | 0.20 | x | — |
| Ex. 3 | 145 | 0.20 | ∘ | ∘ |
| CEx. 3 | 145 | 0.075 | x | — |
| Ex. 4 | 150 | 0.125 | ∘ | ∘ |
| CEx. 4 | 150 | 0.20 | ∘ | x |
| Ex. 5 | 170 | 0.075 | ∘ | ∘ |
| CEx. 5 | 170 | 0.125 | ∘ | x |
| CEx. 6 | 200 | 0.075 | ∘ | x |
| Ex. 6 | 110 | 0.20 | ∘ | ∘ |
| Ex. 7 | 180 | 0.20 | ∘ | ∘ |
| CEx. 7 | 200 | 0.20 | ∘ | x |
| CEx. 8 | 95 | 0.20 | x | — |
| Ex. 8 | 170-180 | 0.20 | ∘ | ∘ |
| Ex. 9 | 90-110 | 0.20 | ∘ | ∘ |
| Ex. 10 | 130-150 | 0.20 | ∘ | ∘ |
| Ex. 11 | 170-180 | 0.20 | ∘ | ∘ |
| Ex. 12 | 220 | 0.20 | ∘ | ∘ |
| CEx. 9 | 250 | 0.20 | ∘ | x |
| Ex. 13 | 110-180 | 0.20 | ∘ | ∘ |
| Ex. 14 | 145-170 | 0.20 | ∘ | ∘ |
| Notes) Ex.: Example, CEx.: Comparative Example, Si: silicon wafer, GaAs: gallium-arsenic wafer, ALN: aluminum nitride type holding substrate, ALO: alumina type holding substrate, PS: polystyrene, EVA: ethylene-vinylalcohol copolymer, PMMA: methacrylate resin, TAC: triacetylcellulose, PE: polyethylene, PP: polypropylene, PVdF: polyvinylidene fluoride, PA6: polyamide-6, mp: melting point, Tg: glass transition temperature, Test result sections: bonding possible: ∘, bonding impossible: x, | | | | |
| # Separated: ∘, not separated: x | | | | |

### Example 15

Semiconductor Wafer (a) and Holding Substrate (b)

The same holding substrate (ALN) as obtained in Example 1 was prepared from the same aluminum nitride-boron nitride porous sintered body as used in Example 1. The same silicon wafer (to be referred to as “Si” hereinafter) having a thickness of 625 μm and a diameter of 125 mm as used in Example 1 was provided.

Adhesive Film (c)

A PET/EVA film (thickness 39 μm; supplied by KURARAY CO., LTD.) in which a polyethylene terephthalate film (PET film, thickness 12 μm, melting point 255° C.) was bonded to an ethylene-vinylalcohol copolymer film (EVA film, thickness 25 μm, melting point 160° C.) with a urethane type adhesive layer (thickness 2 μm), was cut to obtain an adhesive film (c) having a circular form and having a diameter of 152 mm (to be referred to as “PET/EVA” hereinafter).

Bonding of Wafer (Si)/Holding Substrate (b)

The holding substrate (ALN) was laid down, the PET/EVA film was placed thereon so as to bring the EVA surface of the PET/EVA film into contact with the holding substrate (ALN) and the silicon wafer (Si) was placed thereon with positions being adjusted. The resultant set was disposed in a mold made of aluminum alloy with positions being adjusted. The mold was disposed between heat plates of a vacuum press. The vacuum press was an air plunger type. The temperature of the heat plates was increased up to 170° C. in advance.

The pressure in an ambient atmosphere was reduced to 1.3 kPa or less while maintaining the heat plate temperature of 170° C. Then, pressing was carried out by applying a surface pressure of 0.125 MPa and the pressure of 0.125 MPa was maintained for 10 minutes. Then, the reduced pressure in the ambient atmosphere was opened to atmosphere and the press pressure was released. It was allowed to cool to obtain a bonding material of a wafer/holding substrate (to be referred to as “Si/ALN” hereinafter).

The warp of the obtained Si/ALN was +230 μm. Further, the Si/ALN was placed in pure water having a room temperature and ultrasonic vibration was given to the Si/ALN for 30 minutes. However, no separation was found.

Grinding and Polishing of Wafer

Then, the Si/ALN was ground with a grinder until the Si wafer had a thickness of 100 μm.

The Si/ALN was roughly ground with a horizontal precision surface grinding machine (supplied by Okamoto Machine Tool Works, Ltd, GRIND-X SRG-200) using a diamond grinding wheel No. 320 and then ground for finishing with the horizontal surface grinding machine using a diamond grinding wheel No. 2,000, to obtain a thinned Si/ALN.

Separation of Wafer

The thinned Si/ALN was placed in pure water having a temperature of 80° C. and maintained for 1 hours. Then, the thinned Si was separated from the holding substrate with a separating machine. The thickness unevenness of the thinned Si was ±2 μm. Although the adhesive film (PET/EVA) was strongly bonded to the holding substrate (ALN), the adhesive film (PET/EVA) was cleanly separated from the holding substrate (ALN) without any cracks.

### Comparative Example 10

An attempt of bonding was carried out in the same manner as in Example 15 except that the orientation of the adhesive film (c: PET/EVA) was changed so as to bring the EVA surface into contact with the Si wafer surface (so as to bring the PET surface into contact with the holding substrate (ALN)).

As a result, the Si wafer was successfully bonded to the EVA side of the adhesive film (c: PET/EVA). However, the holding substrate (ALN) and the PET side of the adhesive film (c: PET/EVA) could not be bonded to each other.

### Example 16

A thermoplastic polyimide resin (trade name, Rikacoat PA 20: Tg 265° C.: supplied by New Japan Chemical Co., Ltd) consisting of 3,3′, 4,4′-biphenylsulfone tetracarboxylic acid dianhydride and aromatic diamine was dissoleved in N-methylpyrrolidone(=NMP) to prepare a solution having a solid concentration of 20 wt %.

A Si wafer having a thickness of 625 μm and a diameter of 125 mm was coated with the above solution by spin coating. The thickness of the polyimide resin after drying was 2˜3 μm. This polyimide resin-coated Si wafer is to be referred to as “PI-Si wafer” hereinafter. The PI-Si wafer was considered as a Si wafer having a polyimide resin passivation coating, and the PI-Si wafer was subjected to the following tests.

A PI-Si/ALN was obtained in the same manner as in Example 15 except that the Si wafer was replaced with the above PI-Si wafer, that the heat plate temperature for the press bonding was changed from 170° C. to 160° C. and that the surface pressure for the press bonding was changed from 0.125 MPa to 0.2 MPa.

The warp thereof was +190 μM.

Then, the thinning of the PI-Si wafer to a thickness of 100 μm, an adhesive strength alleviation treatment and the separation were carried out in the same manner as in Example 1. The similar results were obtained.

### Comparative Example 11

The bonding was carried out in the same manner as in Example 16 except that a single layer film of an ethylene-vinylalcohol copolymer (EVA, melting point 160° C., thickness 20 μm; supplied by KURARAY CO., LTD.) was used as an adhesive film (c). The obtained wafer/holding substrate was ground and polished until the wafer had a thickness of 100 μm.

Then, the same adhesive strength alleviation treatment as in Example 16 was carried out. Then, an attempt of separation was carried out with a separating machine. However, the separation was impossible. So, the adhesive strength alleviation treatment time was changed to 10 hours. However, the separation was impossible.

### Example 17

A gallium-arsenic mirror wafer having a diameter of 100 mm and a thickness of 625 μm (to be referred to as “GaAs wafer” hereinafter) was coated with a negative photoresist (matrix resin=cyclized rubber) by spincoating, the solvent was removed, and then the coated photoresist was cured with ultraviolet to obtain a resist-coated GaAs wafer having a resist thickness of 2˜3 μm (to be referred to as “CR-GaAs wafer” hereinafter).

As a holding substrate, the same holding substrate (ALO) having a thickness of 1.00 mm and a surface roughness Ra of 0.3 μm as in Example 12 was prepared from the same alumina-boron nitride porous sintered body as used in Example 12.

Further, a PET/EVAc film (thickness 54 μm; supplied by Ryohan packaging system Co., Ltd.) in which a polyethylene terephthalate film (PET film, thickness 12 μm, melting point 255° C.) was bonded to an ethylene-vinyl acetate copolymer film (EVAc film, thickness 40 μm, melting point 90˜95° C.) with a urethane type adhesive layer (thickness 2 μm), was cut to obtain an adhesive film (c) having a circular form and having a diameter of 100 mm (to be referred to as “PET/EVAc” hereinafter).

CR-GaAs/ALO was obtained in the same manner as in Example 15 except that the heat plate temperature for the press bonding was changed from 170° C. to 115° C. and that the constitution of wafer/holding substrate was changed to a constitution in which the holding substrate, the adhesive film and the wafer were stacked with positions being adjusted in the central part of the holding substrate (ALO) such that the EVAc side of the PET/EVAc film came into contact with the holding substrate (ALO) and that the PET side of the PET/EVAc film came into contact with the resin coated surface of the resist-coated GaAs wafer (CR-GaAs). The warp of the CR-GaAs/ALO was +45 μm.

Next, the CR-GaAs/ALO was ground in the same manner as in Example 15 until the wafer had a thickness of 100 μm. An adhesive strength alleviation treatment was carried out in the same manner as in Example 15 except that the treatment time was changed from 1 hour to 3 hours. Then, the separation was carried out. In this case, the separation was successfully carried out between the resist-coated GaAs wafer (CR-GaAs) and the PET.

### Comparative Example 12

The bonding was carried out in the same manner as in Example 17 except that a single layer film of an ethylene-vinylacetate copolymer (EVAc, thickness 25 μm, melting point 90˜95° C.) was used as an adhesive film (c). The obtained wafer/holding substrate was ground and polished until the wafer had a thickness of 100 μm.

Then, the same adhesive strength alleviation treatment as in Example 17 was carried out. Then, an attempt of separation was carried out with a separating machine. However, the separation was impossible. So, the adhesive strength alleviation treatment time was changed to 10 hours. However, the separation was impossible.

### Example 18

In Example 17, the adhesive strength alleviation treatment of the dipping in pure water having a temperature of 80° C. was changed to an adhesive strength alleviation treatment of dipping in a mixed solution of pure water/isopropyl alcohol having a volume ratio of 50/50 and having a temperature of 50° C. The dipping time of 1 hour was sufficient for giving the same results as those in Example 1.

### Example 19

The PET surface of the same PET/EVAc film as used in Example 17 was provided with three lines having a width of 0.2 mm each and a depth of approximately 5 μm each at intervals of 10 mm. The above three lines were made with the back of a cutter.

Example 17 was repeated except that there was used, as a PET/EVAc film used for bonding, the above PET/EVAc film having a PET surface provided with three lines.

As a result, after the wafer/holding substrate was dipped in pure water having a temperature of 80° C. for 1 hour, the separation was successfully carried out.

### Example 20

CR-GaAs/ALO was obtained in the same manner as in Example 17 except that there was used as an adhesive film a two-layered film (thickness 62 μm; supplied by Ryohan packaging system Co., Ltd.) produced by extrusion-laminating polyethylene (PE, melting point 105˜110° C.) on a PET film having a thickness of 12 μm and that the heat plate temperature for the press bonding was changed to 110° C. The warp of the CR-GaAs/ALO was +40 μm. As a result, the separation was successfully carried out between the CR-GaAs and the PET under the same conditions as those in Example 17.

### Example 21

CR-GaAs/ALO was obtained in the same manner as in Example 17 except that there was used as an adhesive film a PET/PE/EVAc three-layered film (thickness 47 μm; supplied by Ryohan packaging system Co., Ltd.) produced by extrusion-laminating polyethylene (PE, melting point 105˜110° C.) and an ethylene-vinyl acetate copolymer (EVAc: melting point 90˜95° C.) on a PET film having a thickness of 12 μm so as to have a polyethylene thickness of 15 μm and have an ethylene-vinyl acetate copolymer thickness of 20 μm, and that the heat plate temperature for the press bonding was changed to 115° C. The warp of the CR-GaAs/ALO was +60 μm.

As a result, after the CR-GaAs/ALO was dipped in pure water having a temperature of 80° C. for 2 hour, the separation was successfully carried out between the CR-GaAs and the PET.

### Example 22

Two kinds of polyimide films of KAPTON 100KJ (trade name; Tg=220° C.; thickness 25 μm; supplied by Du Pont-Toray Co., LTD., to be referred to as “PI-K” hereinafter) and Upilex VT441S (trade name; Tg=270˜280° C.; thickness 25 μm; supplied by Ube Industries, Ltd, to be referred to as “PI-U” hereinafter) were provided as an adhesive film (c).

Gallium-arsenic mirror wafer (to be referred to as “GaAs wafer” hereinafter) having a diameter of 100 mm and a thickness of 625 μm was used as a semiconductor wafer (a).

The same holding substrate (ALO) as obtained in Example 17, the polyimide film PI-K, the polyimide film PI-U and the GaAs wafer were stacked in this order. The stacked holding substrate/polyimide film PI-K/polyimide film PK-U/GaAs wafer were bonded under bonding conditions of a heat plate temperature of 340° C., a surface pressure of 0.2 MPa and a time of 10 minutes. The warp thereof was +100 μm.

In the present Example 22, grinding and thinning were not carried out.

After the obtained wafer/holding substrate was maintained in hot water having a temperature of 80° C. for 3 hours, the separation was carried out with a separating machine. In this case, the wafer was successfully separated between the wafer and the PI-U. Then, the holding substrate (ALO) was easily separated between the holding substrate (ALO) and the PI-K. However, the PI-K and the PI-U were strongly bonded to each other like one polyimide film.

### Comparative Example 13

Example 22 was repeated except that the two kinds of polyimide films of PI-K and PI-U were replaced with one polyimide film PI-K.

After the obtained wafer/holding substrate was maintained in hot water having a temperature of 80° C. for 3 hours, an attempt of separation was carried out with a separating machine. However, the separation was impossible. So, the adhesive strength alleviation treatment time was changed to 10 hours. However, the separation was impossible.

TABLE 2

| | | Holding | | |
|---|---|---|---|---|
| | wafer | substrate | Bonding conditions | |
| | (a) | (b) | Film | temperature |
| Ex. 15 | Si | ALN | PET/EVA | 170 |
| CEx. 10 | Si | ALN | EVA/PET | 170 |
| Ex. 16 | PI-Si | ALN | PET/EVA | 160 |
| CEx. 11 | PI-Si | ALN | EVA | 160 |
| Ex. 17 | CR-GaAs | ALO | PET/EVAc | 120 |
| CEx. 12 | CR-GaAs | ALO | EVAc | 120 |
| Ex. 18 | CR-GaAs | ALO | PET/EVAc | 120 |
| Ex. 19 | CR-GaAs | ALO | PET/EVAc⁽*²⁾ | 120 |
| Ex. 20 | CR-GaAs | ALO | PET/PE | 110 |
| Ex. 21 | CR-GaAs | ALO | PET/PE/EVAc | 115 |
| Ex. 22 | GaAs | ALO | PI-U/PI-K | 340 |
| CEx. 13 | GaAs | ALO | PI-K | 340 |

| | |
|---|---|
| Bonding conditions | Separation conditions |

| | pressure | results | alleviation | results |
|---|---|---|---|---|
| Ex. 15 | 0.125 | ∘ | 1 hour | ∘ |
| CEx. 10 | 0.125 | x | — | — |
| Ex. 16 | 0.2 | ∘ | 1 hour | ∘ |
| CEx. 11 | 0.2 | ∘ | 3 hours | x |
| Ex. 17 | 0.125 | ∘ | 3 hours | ∘ |
| CEx. 12 | 0.125 | ∘ | 3 hours | x |
| Ex. 18 | 0.125 | ∘ | 1 hour⁽*¹⁾ | ∘ |
| Ex. 19 | 0.125 | ∘ | 1 hour | ∘ |
| Ex. 20 | 0.125 | ∘ | 3 hours | ∘ |
| Ex. 21 | 0.125 | ∘ | 2 hours | ∘ |
| Ex. 22 | 0.2 | ∘ | 3 hours | ∘ |
| CEx. 13 | 0.2 | ∘ | 5 hours | x |
| Notes) Ex.: Example, CEx.: Comparative Example, Si: silicon wafer, PI-Si: imide-coated Si, GaAs: gallium-arsenic wafer, CR-GaAs: cyclized rubber-coated GaAs, ALN: aluminum nitride type holding substrate, ALO: alumina type holding substrate, PET: polyethylene terephthalate, EVA: ethylene-vinylalcohol copolymer, EVAc: ethylene-vinyl acetate copolymer, PE: polyethylene, PI-U: polyimide film (Upilex VT441S), PI-K: polyimide film (KAPTON 100KJ), Test result sections: bonding: ∘, bonding | | | | |
| # impossible: x, Separated: ∘, not separated: x | | | | |

⁽*¹⁾: dipping in a solution of pure water/isopropyl alcohol = 1/1 (volume)
⁽*²⁾: three grooves formed on the PET surface

Effect of the Invention

According to the present invention, there is provide a process for the production of a thinned semiconductor wafer, which process can give a thinned wafer which has a high surface accuracy after thinning steps, has little warp, has no residual adhesive thereon and has little cracks in the steps. In the production process of the present invention, further, the wafer is held on the holding substrate with a high degree of reliability during predetermined steps of back surface treatment including thinning steps regardless of the kind of treatment on the circuit surface of the wafer, particularly even when an insulating coating or protective coating of a resin is present on the circuit surface of the wafer. Furthermore, an alleviation treatment is carried out after the treatment of the back surface is finished so that the wafer can be separated at an interface between the wafer and an adhesive film. The adhesive film adhering to the holding substrate can be easily separated from the holding substrate. The process of the present invention has remarkably high industrial significance.

What is claimed is:

1. A process for the production of a thinned wafer, comprising bonding the circuit surface (surface A) of a semiconductor wafer (a) to a holding substrate (b) with an adhesive film (c), grinding and polishing the back surface (surface B) of the semiconductor wafer to thin the semiconductor wafer, carrying out the metallization of the back surface (surface B) and the like as required, and then separating the thinned wafer from the holding substrate (b),
wherein a thermoplastic resin film is used as the adhesive film (c) and the above bonding of the circuit surface (surface A) of the semiconductor wafer (a) to the holding substrate (b) is carried out at a bonding temperature selected from the range of from +10° C. to +120° C. of glass transition point of the thermoplastic resin film or the range of from −40° C. to +20° C. of melting point of the thermoplastic resin film.

2. A process for the production of a thinned wafer according to claim 1, wherein the holding substrate (b) is obtained by impregnating an inorganic continuously porous sintered substrate formed of at least one selected from the group consisting of aluminum nitride, aluminum nitride-boron nitride, silicon carbide, aluminum nitride-silicon carbide-boron nitride, alumina-boron nitride and silicon nitride-boron nitride, with a heat-resistant resin and curing the impregnated heat-resistant resin.

3. A process for the production of a thinned wafer according to claim 1, wherein the bonding is carried out under heat under a reduced pressure under conditions of a pressure selected from 0.05 to 5 Mpa and a treatment time selected from 3 to 90 minutes.

4. A process for the production of a thinned wafer according to claim 1, wherein the adhesive film is a thermoplastic resin film of which both surfaces are different from each other in a glass transition point or melting point and the thermoplastic resin surface (front side) having a higher glass transition point or higher melting point is bonded to the circuit surface (surface A) side of the semiconductor wafer (a).

5. A process for the production of a thinned wafer according to claim 4, wherein the bonding is carried out at a bonding temperature selected from the range of from +10° C. to +120° C. of glass transition point of the thermoplastic resin on that surface (back side) of the thermoplastic resin film which is to be bonded to the holding substrate (b) or the range of from −40° C. to +20° C. of melting point of the thermoplastic resin of the back surface.

6. A process for the production of a thinned wafer according to claim 4, wherein the adhesive film (c) has grooves for a liquid or gas to enter on the thermoplastic resin film surface (front side) to be brought into contact with the circuit surface (surface A) of the wafer (a).

7. A process for the production of a thinned wafer according to claim 1, wherein the separation of the thinned wafer is carried out after the thinned wafer/holding substrate (b) is treated with water, alcohol, a water-alcohol mixed solution or steam having a temperature of from 25 to 140° C.
